(19) United States
(12) Patent Application Publication
(10) Pub. No.: US 2023/0223401 A1
(43) Pub. Date: Jul. 13, 2023

(54) SEMICONDUCTOR DEVICE

(71) Applicant: Fuji Electric Co., Ltd., Kanagawa (JP)

(72) Inventor: Masaharu YAMAJI, Nagano (JP)

(73) Assignee: Fuji Electric Co., Ltd., Kanagawa (JP)

(21) Appl. No.: 18/073,084

(22) Filed: Dec. 1, 2022

(30) Foreign Application Priority Data
Jan. 13, 2022 (JP) 2022-003672

(51) Int. Cl. H01L 27/06; H01L 27/01; H01L 23/522

(52) U.S. Cl. CPC H01L 27/0682; H01L 23/5222; H01L 27/01; H02M 1/34

(57) ABSTRACT

A semiconductor device includes: a lower electrode; a first dielectric layer provided on the lower electrode; a first upper electrode provided on the first dielectric layer; a second dielectric layer provided on the first upper electrode; a second upper electrode provided on the second dielectric layer and electrically connected to the lower electrode; a third dielectric layer provided on the second upper electrode; and a third upper electrode provided on the third dielectric layer and electrically connected to the first upper electrode, wherein a first capacitor between the lower electrode and the first upper electrode, a second capacitor between the first upper electrode and the second upper electrode, and a third capacitor between the second upper electrode and the third upper electrode are connected in parallel with each other.

### BACKGROUND OF THE INVENTION

### Technical Field

The present invention relates to semiconductor devices.

### Background Art

In Patent Document 1, in a power conversion circuit, by connecting an RC snubber circuit in parallel with a power device having a half-bridge configuration that performs switching, a surge voltage generated at the time of turn-off switching of the power device, etc., is absorbed by a capacitance element (snubber capacitor) and consumed as heat by a resistive element of the RC snubber circuit. This RC snubber circuit suppresses surge voltages, which are overshooting and undershooting surge voltages and ringing voltages, and is used to improve the noise resistance of power conversion circuits that handle large power.

In order to reduce the number of passive elements on a printed circuit board in the power conversion circuit and to incorporate them into the power module, a configuration in which a resistive element and a capacitive element are formed on a single chip has been proposed as the configuration of the RC snubber circuit. Patent Literature 2 discloses a snubber circuit chip in which a snubber capacitor is formed by using a semiconductor substrate itself as a resistance element and by embedding an electrode inside a trench in the upper portion of the semiconductor substrate via a dielectric layer to constitute a snubber capacitor.

Patent Document 3 discloses a configuration in which a semiconductor snubber circuit has a substrate region and a dielectric region formed on the substrate region, the substrate region functioning as a resistor and the dielectric region functioning as a capacitor. In Patent Document 4, a drift region and a high resistance layer are provided on a substrate region; a capacitor dielectric region is formed so as to be in contact with the high resistance layer; the substrate region, the drift region and the high resistance layer together function as a resistor; and a capacitor dielectric region functions as a capacitor. Patent Document 5 discloses that both ends of four conductive layers are laid out stepwise, and a capacitive element is formed by a first electrode consisting of odd-numbered conductive layers and a second electrode consisting of even-numbered conductive layers.

### Related Art Document

### Patent Document

Patent Document 1: Japanese Patent Application Laid-Open Publication No. 2007-306692
Patent Document 2: Japanese Patent Publication No. 6889426
Patent Document 3: Japanese Patent Application Laid-Open Publication No. 2010-192827
Patent Document 4: Japanese Patent Application Laid-Open Publication No. 2010-206106
Patent Document 5: Japanese Patent Application Laid-Open Publication No. 2010-98067

### SUMMARY OF THE INVENTION

Normally, in a high-power power conversion circuit, although it depends on the voltage of the AC power supply, the surge voltage at the time of turn-off switching of the power device is as high as 1000 V. Thus, the withstand voltage of the snubber capacitor that is connected in parallel to the power device is also required to be about 1000 V. In order to form a thick dielectric layer corresponding to such high withstand voltage specifications in a trench shape like the snubber capacitor of the snubber circuit chip described in Patent Document 2, it is necessary to form a wide trench. This poses difficulties in obtaining the effect of reducing the area of the capacitor portion.

Although it depends on the current rating of the power device, it is generally necessary to create a capacitance value of 1 nF or more as a capacitance value necessary for suppressing surge voltage. Assuming that a planar snubber capacitor with an oxide film thickness d of 3 µm with the dielectric constant ε of 3.9 (assuming a film quality such as a TEOS film with a dielectric breakdown field strength of about 3.3 MV/cm) is required for the 1000 V withstand voltage, from C = ε × S/d, it can be seen that the area of the capacitor portion required for a capacitance value of 1 nF is 9.32 mm×9.32 mm, which is as large a chip area as the power device. As a result, there is a problem that it becomes difficult to reduce the area of the printed circuit board that constitutes the power conversion circuit and also is difficult to incorporate it into the power module.

In view of the foregoing, an object of the present invention is to provide a semiconductor device that can realize a high withstand voltage capacitive element having a small chip area.

Additional or separate features and advantages of the invention will be set forth in the descriptions that follow and in part will be apparent from the description, or may be learned by practice of the invention. The objectives and other advantages of the invention will be realized and attained by the structure particularly pointed out in the written description and claims thereof as well as the appended drawings.

To achieve these and other advantages and in accordance with the purpose of the present invention, as embodied and broadly described, in one aspect, the present disclosure provides a semiconductor device, comprising: a lower electrode; a first dielectric layer provided on the lower electrode; a first upper electrode provided on the first dielectric layer; a second dielectric layer provided on the first upper electrode; a second upper electrode provided on the second dielectric layer and electrically connected to the lower electrode; a third dielectric layer provided on the second upper electrode; and a third upper electrode provided on the third dielectric layer and electrically connected to the first upper electrode, wherein a first capacitor between the lower electrode and the first upper electrode, a second capacitor between the first upper electrode and the second upper electrode, and a third capacitor between the second upper electrode and the third upper electrode are connected in parallel with each other.

According to the present invention, it is possible to provide a semiconductor device capable of realizing a high withstand voltage capacitive element with a small chip area.

It is to be understood that both the foregoing general description and the following detailed description are exemplary and explanatory, and are intended to provide further explanation of the invention as claimed.

### BRIEF DESCRIPTION OF THE DRAWINGS

FIG. 1 is a circuit diagram showing a power conversion circuit to which a semiconductor device according to a first embodiment is applied.

FIG. 2 is a plan view showing a semiconductor device according to a first embodiment.

FIG. 3 is a sectional view seen from the A-A direction of FIG. 1.

FIG. 4 is a cross-sectional view in which an equivalent circuit is superimposed on FIG. 3.

FIG. 5 is a cross-sectional view for explaining a method of manufacturing the semiconductor device according to the first embodiment;

FIG. 6 is a cross-sectional view continued from FIG. 5 for explaining the method of manufacturing the semiconductor device according to the first embodiment.

FIG. 7 is a cross-sectional view continued from FIG. 6 for explaining the method of manufacturing the semiconductor device according to the first embodiment.

FIG. 8 is a cross-sectional view continued from FIG. 7 for explaining the method of manufacturing the semiconductor device according to the first embodiment.

FIG. 9 is a cross-sectional view continued from FIG. 8 for explaining the method of manufacturing the semiconductor device according to the first embodiment.

FIG. 10 is a cross-sectional view continued from FIG. 9 for explaining the method of manufacturing the semiconductor device according to the first embodiment.

FIG. 11 is a cross-sectional view continued from FIG. 10 for explaining the method of manufacturing the semiconductor device according to the first embodiment.

FIG. 12 is a cross-sectional view continued from FIG. 11 for explaining the manufacturing method of the semiconductor device according to the first embodiment.

FIG. 13 is a cross-sectional view continued from FIG. 12 for explaining the method of manufacturing the semiconductor device according to the first embodiment.

FIG. 14 is a cross-sectional view showing a semiconductor device according to a second embodiment.

FIG. 15 is a cross-sectional view in which an equivalent circuit is superimposed on FIG. 14.

FIG. 16 is a plan view showing a resistance layer of a semiconductor device according to a second embodiment.

FIG. 17 is a plan view showing another example of the resistance layer of the semiconductor device according to the second embodiment.

FIG. 18 is a cross-sectional view showing a semiconductor device according to a third embodiment.

FIG. 19 is a cross-sectional view showing another example of the semiconductor device according to the third embodiment.

FIG. 20 is a cross-sectional view showing a semiconductor device according to a fourth embodiment.

FIG. 21 is a plan view showing another example of the semiconductor device according to the fourth embodiment.

### DETAILED DESCRIPTION OF EMBODIMENTS

The first to fourth embodiments of the present invention and their modifications will be described below with reference to the drawings. In the description of the drawings, the same or similar parts are denoted by the same or similar reference numerals, and overlapping descriptions are omitted. However, the drawings are schematic, and the relationship between the thickness and the planar dimensions, the ratio of the thickness of each layer, and the like may differ from the actual ones. In addition, portions having different dimensional relationships and ratios may also be included between drawings. In addition, the first to fourth embodiments shown below exemplify apparatuses and methods for embodying the technical idea of the present invention, and the shape, structure, arrangement, etc., are not limited by these embodiments.

Also, the definitions of directions such as up, down, left and right in the following description are merely definitions for convenience of description and do not limit the technical idea of the present invention. For example, if an object is observed after being rotated by 90°, it will be read with its top and bottom converted to left and right, and if it is observed after being rotated by 180°, it will, of course, be read with its top and bottom reversed.

### First Embodiment

### Semiconductor Device Configuration

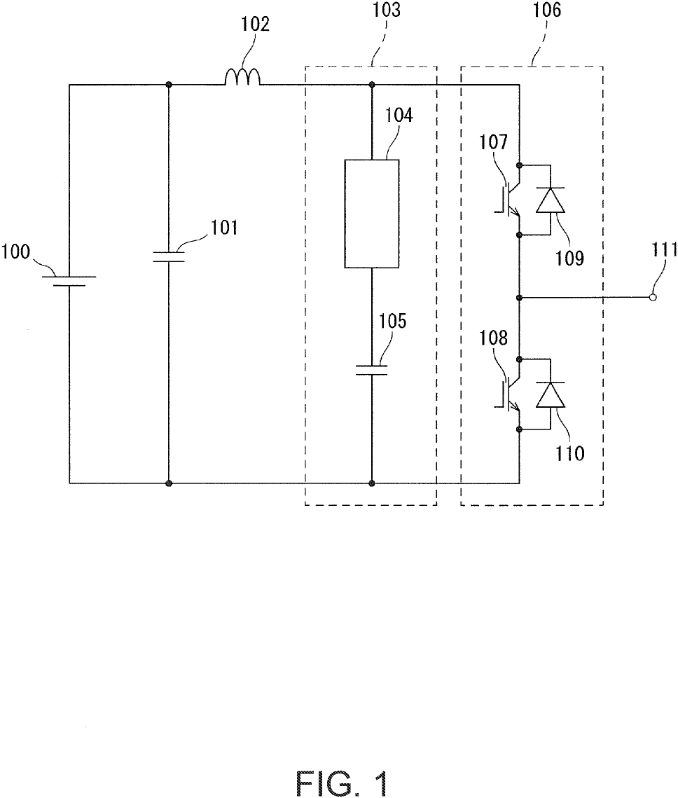

The semiconductor device according to the first embodiment of the present invention is applied to a power conversion circuit, for example, as a snubber circuit (RC snubber circuit) 103, as shown in FIG. 1. The power conversion circuit includes a DC power supply 100 , a smoothing capacitor 101, a main circuit inductance 102, a snubber circuit 103, and a power conversion section 106.

The power converter 106 configures a half bridge circuit by connecting a high potential side switching element 107 and a low potential side switching element 108, which are power devices, in series. Freewheeling diodes 109 and 110 are connected in anti-parallel to the switching element 107 on the high potential side and the switching element 108 on the low potential side, respectively. In FIG. 1, an insulated gate bipolar transistor (IGBT) is exemplified as the high potential side switching element 107 and the low potential side switching element 108, but the high potential side switching element 107 and the low potential side switching element 108 may be other power switching elements, such as metal oxide semiconductor field effect transistors (MOSFETs). If MOSFETs are used as switching elements, free wheel diodes 109 and 110 may not be used.

The collector of the high potential side switching element 107 is connected to the positive electrode side of the DC power supply 100 via the main circuit inductance 102. The emitter of the low potential side switching element 108 is connected to the negative electrode side of the DC power supply 100 on the low potential side. A load (not shown) such as a motor is connected to a connection point 111 between the emitter of the high potential side switching element 107 and the collector of the low potential side switching element 108.

The smoothing capacitor 101 is connected in parallel with the DC power supply 100. A DC voltage supplied from the DC power supply 100 is smoothed by a smoothing capacitor 101 and applied to a power converter 106 via a main circuit inductance 102.

The snubber circuit 103 is connected in parallel with the high potential side switching element 107 and the low potential side switching element 108. The snubber circuit 103 includes a resistor 104 one end of which is connected to the collector of the high potential side switching element 107 and a capacitor (snubber capacitor) 105 one end of which is connected to the other end of the resistor 104 and the other end of which is connected to the emitter of the low potential side switching element 108.

The snubber circuit 103 absorbs the surge voltage generated at the time of turn-off switching of the high-potential switching element 107 and the low-potential switching element 108 with the snubber capacitor 105 and dissipates it as heat in the resistor 104, thereby suppressing the surge voltage and ringing voltage and improving the noise resistance.

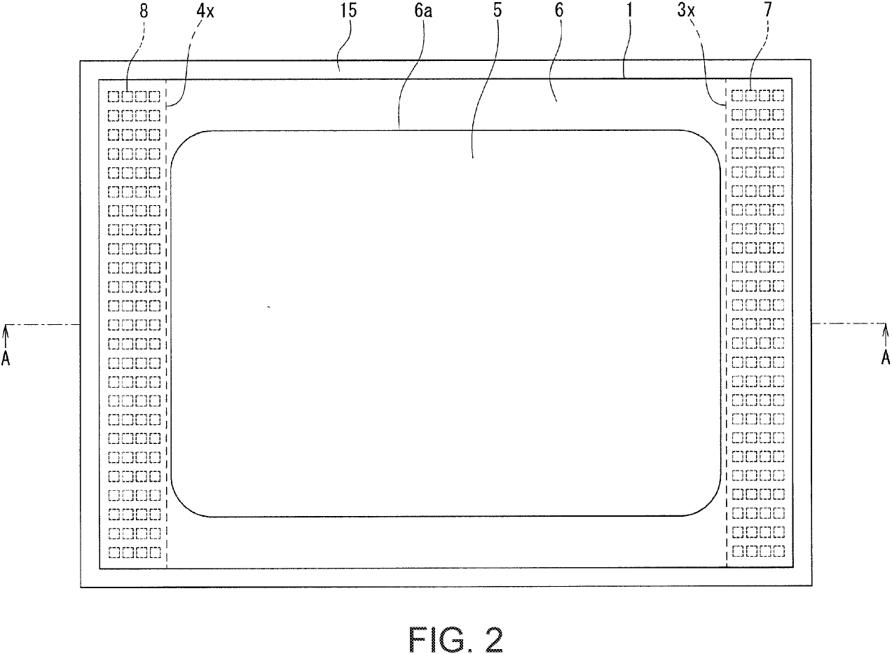

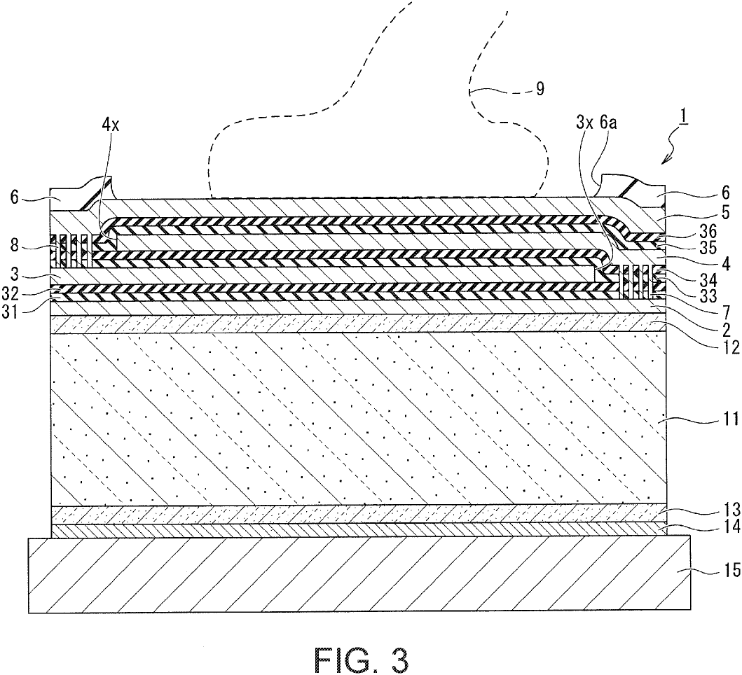

FIG. 2 is a plan view of the semiconductor device 1 according to the first embodiment, and FIG. 3 is a cross-sectional view of FIG. 2 as seen from the A-A direction. The semiconductor device 1 according to the first embodiment is a snubber circuit chip (passive element chip) corresponding to the snubber circuit 103 shown in FIG. 1. As shown in FIG. 2, the semiconductor device 1 according to the first embodiment has a substantially rectangular planar shape.

As shown in FIG. 3, the semiconductor device 1 according to the first embodiment includes a semiconductor substrate 11. The conductivity type of the semiconductor substrate 11 is not particularly limited. The semiconductor substrate 11 is composed of, for example, a silicon (Si) substrate. The semiconductor substrate 11 may instead be composed of a semiconductor substrate made of silicon carbide (SiC), gallium nitride (GaN), gallium arsenide (GaAs), diamond, or the like.

A high-concentration region 12 having the same conductivity type as the semiconductor substrate 11 and having a higher impurity concentration than the semiconductor substrate 11 is provided on the upper surface side (upper portion) of the semiconductor substrate 11. For example, a p-type semiconductor substrate 11 is provided with a p⁺-type high concentration region 12, and alternatively, an n-type semiconductor substrate 11 is provided with an n⁺-type high concentration region 12. A lower electrode 2 is provided on the upper surface of the high-concentration region 12. The lower electrode 2 is in ohmic contact with the high concentration region 12. The planar shape of the lower electrode 2 is rectangular and matches the planar shape of the semiconductor device 1 of the first embodiment shown in FIG. 2.

A first upper electrode 3, which is a metal electrode, is provided over the upper surface of the lower electrode 2 via dielectric layers (31, 32), which are intermetal dielectric (IMD) films. The dielectric layers (31, 32) include a dielectric film 31 in contact with the upper surface of the lower electrode 2 and a dielectric film 32 provided on the dielectric film 31 and in contact with the lower surface of the first upper electrode 3. The lower electrode 2, the dielectric layers (31, 32) and the first upper electrode 3 form a metal-insulator-metal (MIM) type capacitive element (2, 3, 31, 32).

A second upper electrode 4, which is a metal electrode, is provided over the upper surface of the first upper electrode 3 via dielectric layers (33, 34), which are IMD films. The dielectric layers (33, 33) include a dielectric film 33 in contact with the upper surface of the first upper electrode 3 and a dielectric film 34 provided on the dielectric film 33 and in contact with the lower surface of the second upper electrode 4. The first upper electrode 3, the dielectric layers (33, 34), and the second upper electrode 4 constitute a MIM type capacitive element (3, 4, 33, 34).

A third upper electrode 5, which is a metal electrode, is provided over the upper surface of the second upper electrode 4 via dielectric layers (35, 36), which are IMD films. The dielectric layers (35, 36) include a dielectric film 35 in contact with the upper surface of the second upper electrode 4 and a dielectric film 36 provided on the dielectric film 35 and in contact with the lower surface of the third upper electrode 5. The second upper electrode 4, the dielectric layers (35, 36), and the third upper electrode 5 constitute a MIM type capacitive element (4, 5, 35, 36).

As materials for the lower electrode 2, the first upper electrode 3, the second upper electrode 4, and the third upper electrode 5, metals such as aluminum (Al), Al alloys, and copper (Cu) can be used. The Al alloys may be Al-silicon (Si), Al-copper (Cu)—Si, Al—Cu, and the like. As the materials for the lower electrode 2, the first upper electrode 3, the second upper electrode 4, and the third upper electrode 5, conductive materials other than metals may be used. The lower electrode 2, the first upper electrode 3, the second upper electrode 4, and the third upper electrode 5 may be made of polysilicon heavily doped with p-type or n-type impurities to form polysilicon-insulator-polysilicon (PIP) type capacitive elements instead.

The materials of the lower electrode 2, the first upper electrode 3, the second upper electrode 4 and the third upper electrode 5 may be the same or different from each other. The thicknesses of the lower electrode 2, the first upper electrode 3, the second upper electrode 4, and the third upper electrode 5 may be the same or different from each other

Each of the dielectric layer (31, 32), the dielectric layer (33, 34), and the dielectric layer (35, 36) has a two-layer structure, but may have a single-layer structure or a multi-layer structure of three or more layers. The materials and number of layers of the dielectric layer (31, 32), dielectric layer (33, 34) and dielectric layer (35, 36) may be the same or different from each other. The thicknesses of the dielectric layer (31, 32), the dielectric layer (33, 34) and the dielectric layer (35, 36) may be the same or different from each other.

The material of the dielectric films 31 to 36 may be, for example, a silicon oxide film (SiO₂ film), and in particular, may be a silicon oxide film (SiO₂ film), which is referred to as a non-doped silica glass film (NSG film), containing neither phosphorus (P) nor boron (B), a silicon oxide film to which phosphorus is added (PSG film), a silicon oxide film to which boron is added (BSG film), a silicon oxide film to which phosphorus and boron are added (BPSG film), or a silicon nitride film (Si₃N₄ film). The dielectric films 31 to 36 may also be insulating films (TEOS films) formed by a chemical vapor deposition (CVD) method or the like using tetraethoxysilane (TEOS) gas of an organic silicon compound.

For example, as the structure of the dielectric layers (31, 32), the dielectric film 31 may be composed of a TEOS film with a thickness of about 3 µm, and the dielectric film 32 may be composed of a PSG film. By making the coefficients of thermal expansion of the dielectric films 31 and 32 different from each other, the internal stress can be offset, and even if the dielectric film 31 is a thick oxide film of about 3 µm, warping of the wafer can be prevented and flatness of the wafer can be maintained.

The lower electrode 2 and the second upper electrode 4 are electrically connected to each other through connection conductors (vias) 7 penetrating the dielectric layers (31, 32) and dielectric layers (33, 34). The first upper electrode 3 and the third upper electrode 5 are electrically connected via connection conductors (vias) 8 penetrating the dielectric layers (33, 34) and the dielectric layers (35, 36). The number of the vias 7 and 8 is not particularly limited. The lower electrode 2 and the second upper electrode 4 are connected by vias 7 passing through the dielectric layers while leaving the dielectric layers (31, 32) between the lower electrode 2 and the second upper electrode 4. Therefore, a capacitor C3 composed of the second upper electrode 4, the dielectric layers (35, 36), and the third upper electrode 5 can be formed above the via 7 as well. Therefore, the area of the capacitor C3 can be efficiently formed.

In FIG. 2, the positions of the vias 7 and 8, the position of the end 3x of the first upper electrode 3, and the position of the end 4x of the second upper electrode 4 are schematically indicated by broken lines. As shown in FIG. 2, the vias 7 are arranged on one side of the rectangle formed by the plane pattern of the semiconductor device 1 in the first embodiment, and are spaced apart from the end 3x of the first upper electrode 3. As shown in FIG. 2, the end 3x of the first upper electrode 3 on the side of the vias 7 is positioned inward from the end of the semiconductor device 1 in order for the vias 7 to be arranged. The vias 8 are arranged on the side opposite to the side on which the vias 7 are formed in the planar pattern of the semiconductor device 1 in the first embodiment, and are spaced apart from the end 4x of the second upper electrode 4. The 4x of the second upper electrode 4 on the side of the via 8 is positioned inward from the end of the semiconductor device 1 in order for the vias 8 to be arranged.

As shown in FIGS. 2 and 3, the third upper electrode 5 is the uppermost electrode, and a protective film 6 is provided on the upper surface of the third upper electrode 5. The protective film 6 is composed of, for example, a TEOS film, a Si₃N₄ film, or a polyimide film. For example, the protective film 6 may instead be composed of a composite film in which a TEOS film, a Si₃N₄ film and a polyimide film are laminated in this order. The protective film 6 is provided with an opening 6 a that exposes a portion of the upper surface of the third upper electrode 5. The opening 6a constitutes a bonding pad for bonding a bonding wire 9 schematically indicated by the dashed line in FIG. 3.

A high-concentration region 13 having the same conductivity type as the semiconductor substrate 11 and having a higher impurity concentration than the semiconductor substrate 11 is provided on the lower surface side (lower portion) of the semiconductor substrate 11. A back electrode 14 is provided on the lower surface of the high-concentration region 13. The back electrode 14 can be composed of, for example, a single layer film made of gold (Au) or a metal film in which titanium (Ti), nickel (Ni) and gold (Au) are laminated in this order. The bottom surface of the back electrode 14 of the semiconductor device 1 of the first embodiment is bonded to the die pad 15.

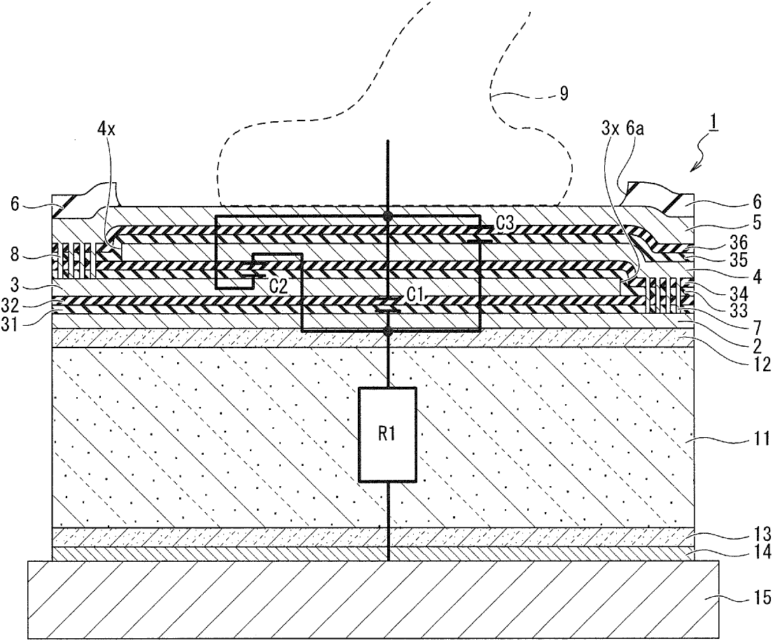

FIG. 4 schematically shows an equivalent circuit superimposed on the cross section of the semiconductor device 1 of the first embodiment shown in FIG. 3. As shown in FIG. 4, the capacitor C1 of the capacitive element (2, 3, 31, 32) constituted by the lower electrode 2, the dielectric layers (31, 32) and the first upper electrode 3, the capacitor C2 of the capacitive element (3, 4, 33, 34) constituted by the first upper electrode 3, the dielectric layers (33, 34) and the second upper electrode 4, the capacitor C3 of capacitive elements (4, 5, 35, 36) constituted by the second upper electrode 4, the dielectric layers (35, 36) and third upper electrode 5 are connected in parallel with each other. The capacitors C1, C2 and C3 are connected in series with resistor R1, which is a resistive element formed by semiconductor substrate 11. The capacitors C1, C2 and C3 shown in FIG. 4 correspond to the capacitor 105 of the snubber circuit 103 shown in FIG. 1, and the resistor R1 shown in FIG. 4 corresponds to the resistor 104 of the snubber circuit 103 shown in FIG. 1.

According to the semiconductor device 1 of the first embodiment, by alternately stacking, on the lower electrode 2, the dielectric layers (31, 32), the dielectric layers (33, 34), and the dielectric layers (35, 36), which are IMDs, with the first upper electrode 3, the second upper electrode 4, and the third upper electrode 5, which are metal electrodes, and by connecting the capacitors C1, C2, and C3 in parallel, the dielectric layers (31, 32), the dielectric layers (33, 34), and the dielectric layers (35, 36) each having a thickness of 3 µmcan be formed without causing cracks and transfer failures due to wafer warpage. This way, the high-withstand voltage capacitors C1, C2, C3 with the capacitance of nF-order can be realized. In addition, by connecting the capacitors C1, C2, and C3 in parallel, when a capacitance value of 1 nF needs to be created, for example, the area of the capacitor portion needs to be only 5.38 mm×5.38 mm. Thus, the chip area can be reduced by about 42%. Therefore, for example, an RC snubber circuit chip that requires a high withstand voltage and a large capacitance value can be realized with a small chip area. As a result, the area of the printed circuit board in the power conversion circuit can be saved, and the chip can be built into the power module and miniaturized.

Furthermore, since the resistive element formed by the semiconductor substrate 11 is also in ohmic contact with the high-concentration region 12, it is possible to realize stable resistance characteristics with small variations, and to stably suppress surge voltage during switching of the power device.

### Manufacturing Method of Semiconductor Device

Next, an example of a method for manufacturing the semiconductor device 1 of the first embodiment will be described. The manufacturing method of the semiconductor device 1 of the first embodiment described below is merely an example, and various other manufacturing methods, including modifications to this example, are possible.

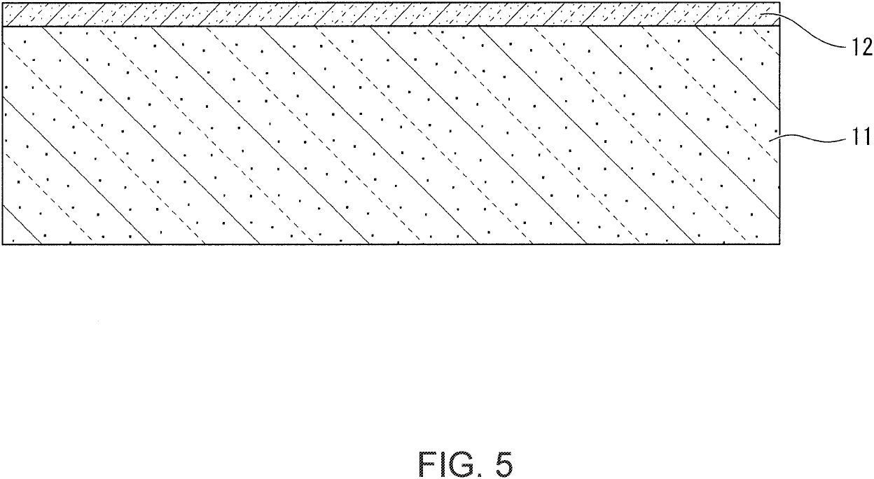

First, an n-type impurity such as phosphorus (P) or arsenic (As) is ion-implanted into the upper surface of an n-type semiconductor substrate 11, and heat treatment (annealing) is performed to form an n+-type high-concentration region 12 in an upper portion of the semiconductor substrate 11 as shown in FIG. 5. The ion implantation may be performed through a buffer oxide film.

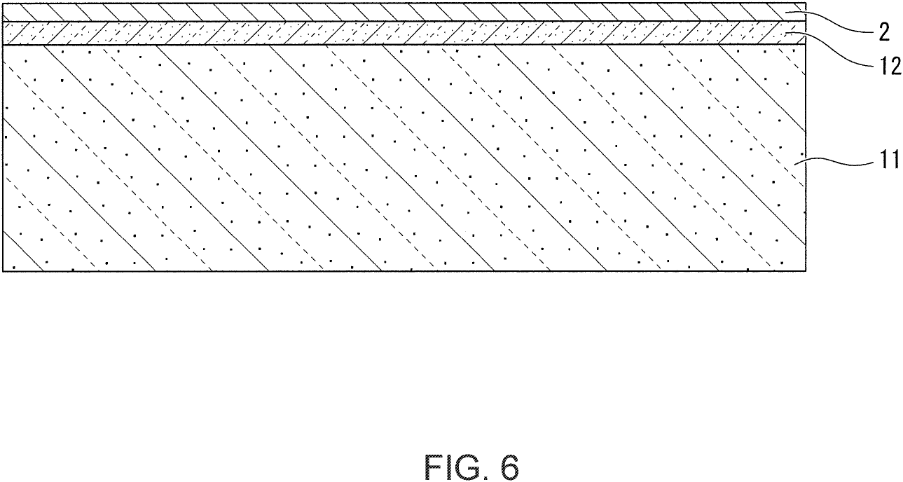

Next, as shown in FIG. 6, the lower electrode 2 made of aluminum or the like is deposited on the high-concentration region 12 by sputtering, vapor deposition, or the like. The lower electrode 2 is in ohmic contact with the high concentration region 12.

Next, dielectric layers (31, 32) are formed by sequentially depositing a dielectric film 31 and a dielectric film 32 on the lower electrode 2 by a chemical vapor deposition (CVD) method or the like. For example, an oxide film such as a TEOS film is deposited to a thickness of about 3 µm as the dielectric film 31 and a PSG film is deposited as the dielectric film 32. By making the coefficients of thermal expansion of the dielectric films 31 and 32 different, it is possible to cancel the internal stress, to prevent warping of the wafer, and to maintain the flatness of the wafer even with the oxide film as thick as 3 µm.

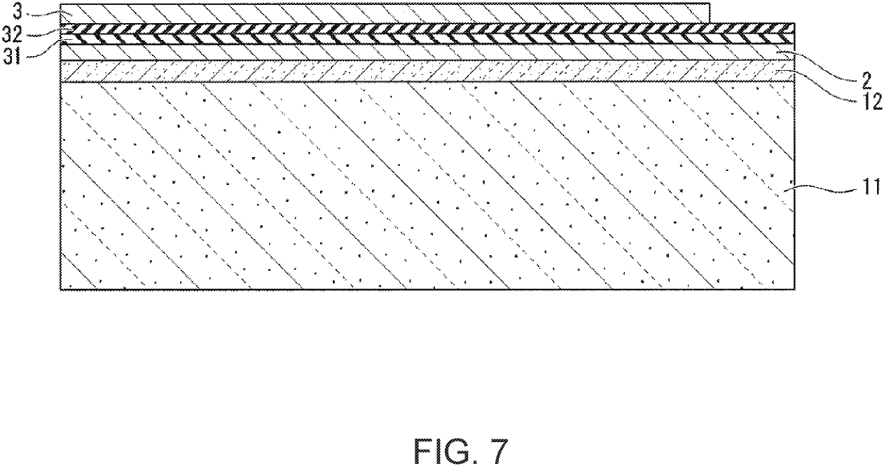

Next, the first upper electrode 3 made of aluminum or the like is deposited on the upper surfaces of the dielectric layers (31, 32) by sputtering, vapor deposition, or the like. A photoresist film is applied on the first upper electrode 3, and the photoresist film is patterned using a photolithographic technique. Using the patterned photoresist film as an etching mask, a portion of the first upper electrode 3 is selectively removed by dry etching such as reactive ion etching (RIE). After that, the photoresist film is removed. As a result, as shown in FIG. 7, a portion of the upper surface of the dielectric film 32 is exposed.

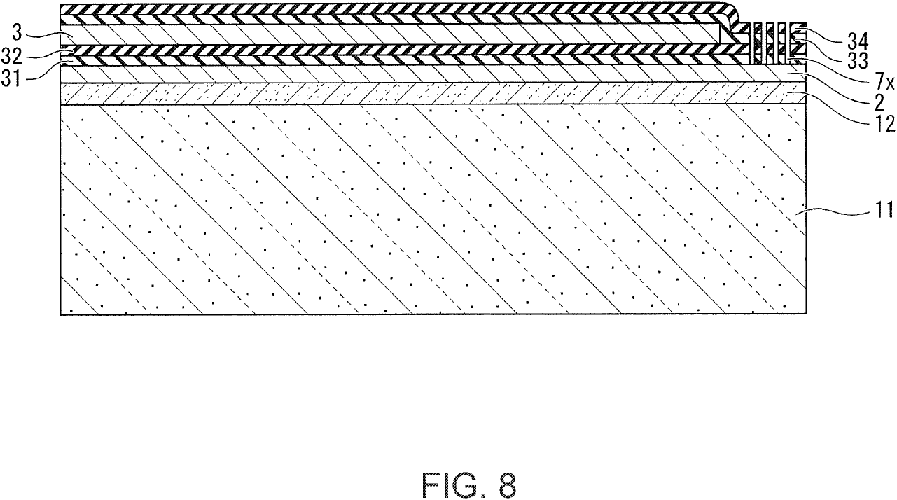

Next, dielectric layers (33, 34) are formed by sequentially depositing a dielectric film 33 and a dielectric film 34 on the first upper electrode 3 and the dielectric film 32 by CVD or the like. A photoresist film is applied on the dielectric film 34, and the photoresist film is patterned using a photolithographic technique. Using the patterned photoresist film as an etching mask, portions of the dielectric layers (31, 32) and the dielectric layers (33, 34) are selectively removed by dry etching or the like. After that, the photoresist film is removed. As a result, as shown in FIG. 8, contact holes 7x that penetrate the dielectric layers (31, 32) and the dielectric layers (33, 34) and that reach the lower electrode 2 are formed.

Next, the vias 7 are formed by filling the contact holes 7x with tungsten (W) by the CVD method or the like or copper (Cu) plating. Next, the second upper electrode 4 made of aluminum or the like is deposited on the dielectric film 34 by sputtering, vapor deposition, or the like so as to be in contact with the upper ends of the vias 7. If the contact holes 7x are formed by round etching with a wide width, the vias 7 may instead be formed at the same time as the second upper electrode 4 is formed, by filling in the contact holes 7x with aluminum or the like.

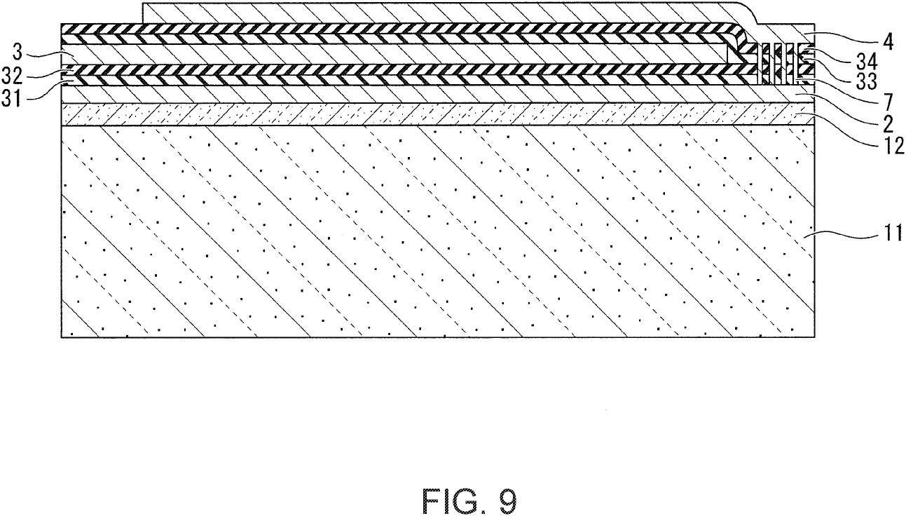

Next, a photoresist film is applied onto the second upper electrode 4, and the photoresist film is patterned using a photolithography technique. Using the patterned photoresist film as an etching mask, a portion of the second upper electrode 4 is selectively removed by dry etching or the like. After that, the photoresist film is removed. As a result, as shown in FIG. 9, a portion of the upper surface of the dielectric film 34 is exposed.

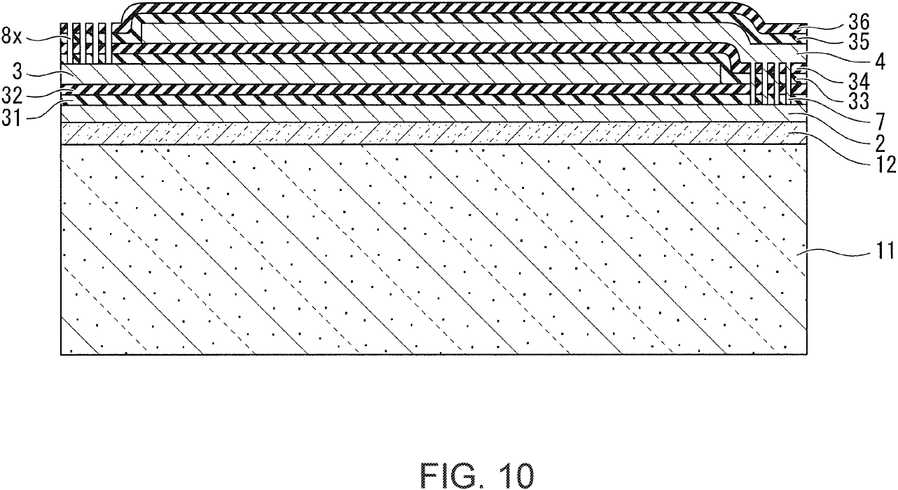

Next, dielectric layers (35, 36) are formed by sequentially depositing a dielectric film 35 and a dielectric film 36 on the second upper electrode 4 and the dielectric film 34 by CVD or the like. A photoresist film is applied on the dielectric film 36, and the photoresist film is patterned using a photolithographic technique. Using the patterned photoresist film as an etching mask, portions of the dielectric layers (33, 34) and the dielectric layers (35, 36) are selectively removed by dry etching or the like. After that, the photoresist film is removed. As a result, as shown in FIG. 10, contact holes 8x that penetrate the dielectric layers (33, 34) and the dielectric layers (35, 36) and that reach the first upper electrode 3 are formed.

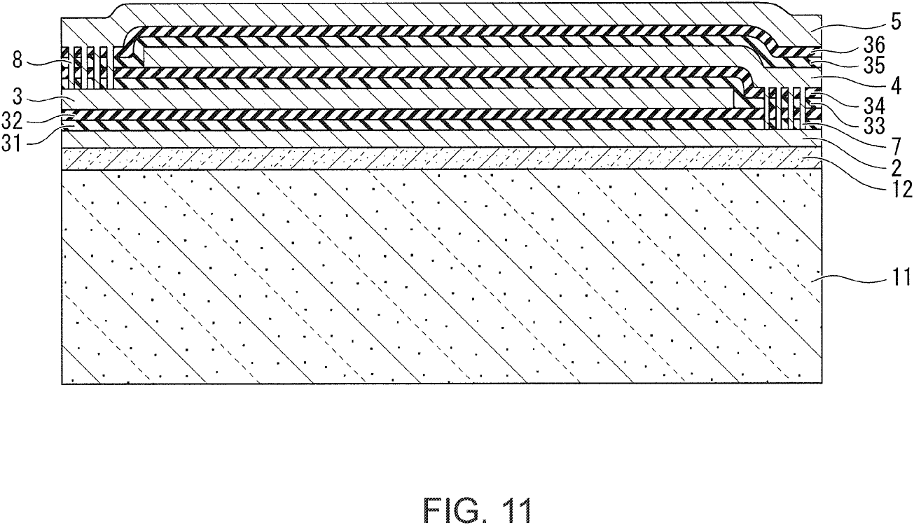

Next, vias 8 are formed by filling the contact holes 8x with tungsten (W) by the CVD method or copper (Cu) plating or the like. Next, as shown in FIG. 11, the third upper electrode 5 made of aluminum or the like is deposited on the dielectric film 36 by sputtering, vapor deposition, or the like. If the contact holes 8x are formed by round etching with a wide width, the contact holes 8x may instead be filled with aluminum or the like when the third upper electrode 5 is deposited, so that the vias 8 are formed at the same time as the third upper electrode 5 is formed.

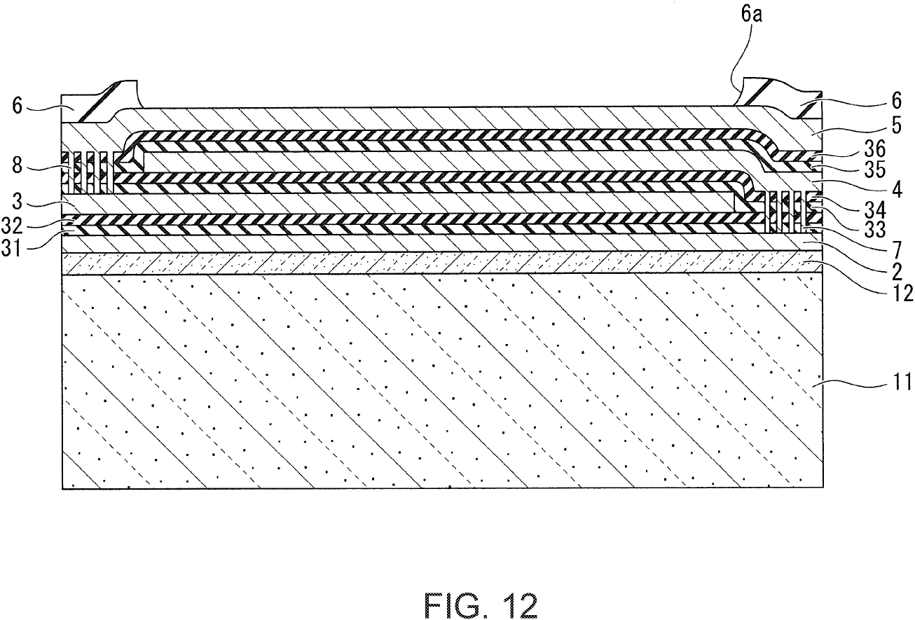

Next, a protective film 6 such as a Si₃N₄ film is formed on the third upper electrode 5 by plasma CVD or the like. A photoresist film is applied on the protective film 6, and the photoresist film is patterned using a photolithographic technique. A portion of the protective film 6 is selectively removed by dry etching or the like using the patterned photoresist film as an etching mask. As a result, as shown in FIG. 12, an opening 6a is formed in the protective film 6, and a portion of the third upper electrode 5 exposed in the opening 6a becomes a pad area capable of wire bonding.

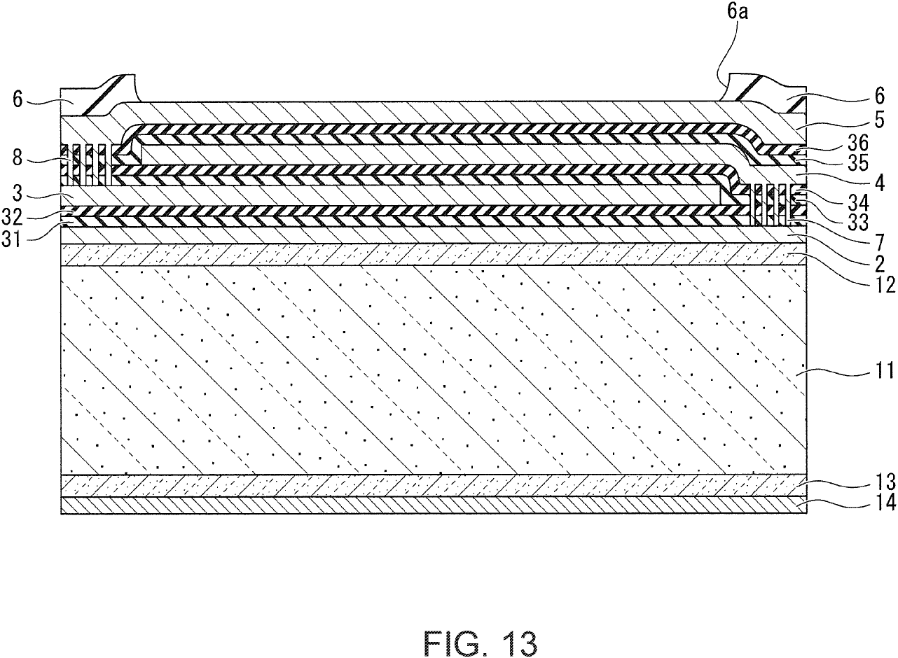

Next, an n-type impurity such as phosphorus (P) or arsenic (As) is ion-implanted into the back surface of the semiconductor substrate 11 and is heat-treated (annealed) to form an n⁺-type high-concentration region 13 under the semiconductor substrate 11. Next, as shown in FIG. 13, the back electrode 14 is deposited on the lower surface of the high-concentration region 13 by sputtering, vapor deposition, or the like. As a result, the semiconductor device 1 of the first embodiment is completed.

### Second Embodiment

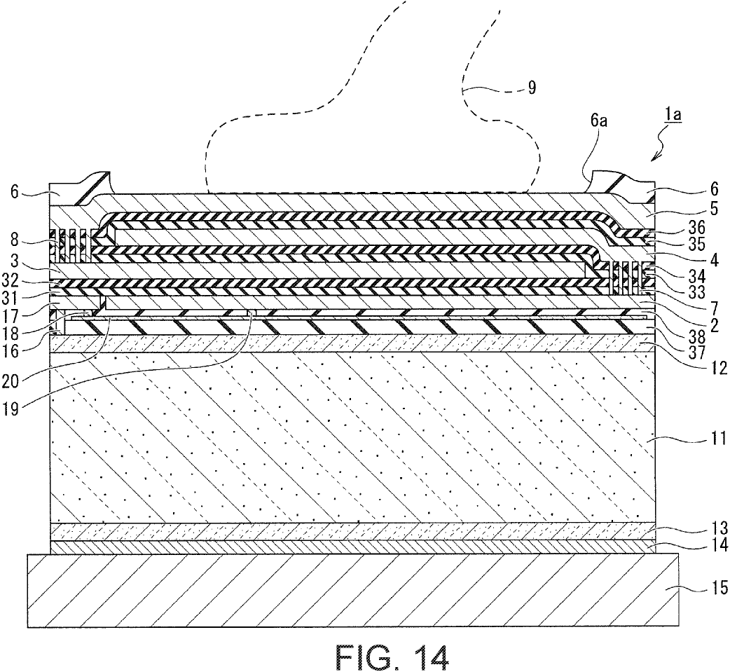

As shown in FIG. 14, a semiconductor device 1a according to a second embodiment differs from the semiconductor device 1 of the first embodiment in that it further includes a thin-film resistance layer 20 on the semiconductor substrate 11 with an insulating film 37 interposed therebetween. The high-concentration region 12 on the upper surface side of the semiconductor substrate 11 is connected to a relay wiring 17 through a via 16 penetrating insulating films 37 and 38. The lower end of the via 16 and the upper surface of high concentration region 12 are in ohmic contact with each other. The relay wiring 17 is provided in the same layer as the lower electrode 2 and is separated from the lower electrode 2. The relay wiring 17 is connected to the upper surface of the resistance layer 20 through a via 18 penetrating the insulating film 38. The upper surface of the resistance layer 20 is connected to the lower surface of the lower electrode 2 through a via 19 penetrating the insulating film 38.

The resistance layer 20 is composed of a polysilicon resistor made of, for example, a polysilicon film. A region of the resistance layer 20 between the vias 18 and 19 functions as a resistor. By adjusting the width and length of the resistance layer 20 and the concentration of n-type or p-type impurities added to the resistance layer 20, the resistance value of the resistance layer 20 can be appropriately adjusted. Also, the resistance value of the resistance layer 20 can be adjusted by adjusting the positions of the vias 18 and 19.

The resistance layer 20 may have a zero temperature coefficient, a positive temperature coefficient, or a negative temperature coefficient. When the resistance layer 20 has a negative temperature coefficient, it is possible to suppress an increase in resistance during high-temperature operation. The temperature coefficient of the resistance layer 20 can be adjusted, for example, by adjusting the dose amount when ion-implanting impurities into polysilicon.

Note that the resistance layer 20 is not limited to a polysilicon film, and may be a transition metal nitride film, such as tantalum nitride (TaNx), or a laminated film of refractory metal films laminated in the order of chromium (Cr)-nickel (Ni)-manganese (Mn). Also, the resistance layer 20 may be a thin film of silver palladium (AgPd), ruthenium oxide (RuO₂), or the like.

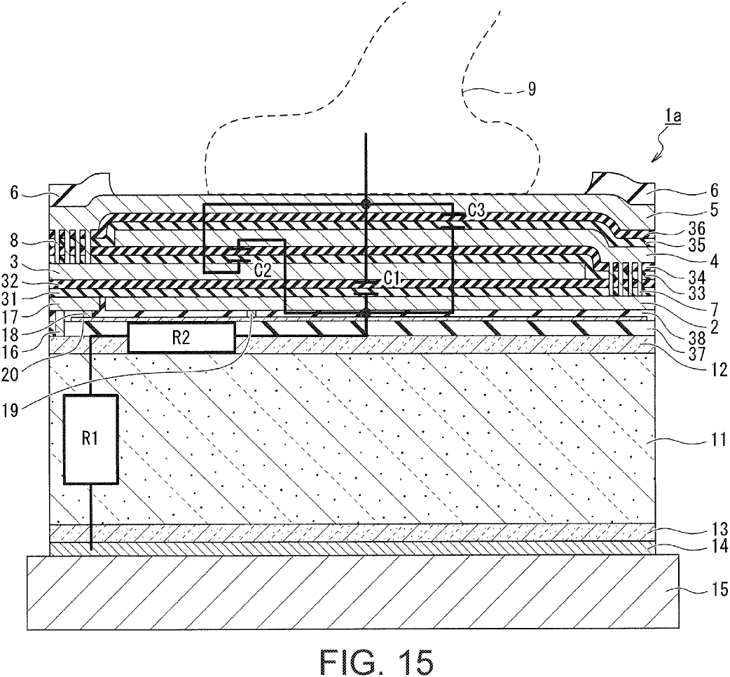

FIG. 15 schematically shows an equivalent circuit superimposed on the cross section of the semiconductor device 1a of the second embodiment shown in FIG. 14. As shown in FIG. 15, the capacitor C1 of the capacitive element (2, 3, 31, 32) constituted by the lower electrode 2, the dielectric layers (31, 32), and the first upper electrode 3, the capacitor C2 of the capacitive element (3, 4, 33, 34) constituted by the first upper electrode 3, the dielectric layers (33, 34), and the second upper electrode 4, and the capacitor C3 of the capacitive element (4, 5, 35, 36) constituted by the second upper electrode 4, the dielectric layers (35, 36), and the third upper electrode 5 are connected in parallel with each other. The capacitors C1, C2, and C3 are connected in series with a resistor R2 of the resistive element formed by the resistance layer 20 and a resistor R1 of the resistive element formed by the semiconductor substrate 11 so as to form an RC snubber circuit.

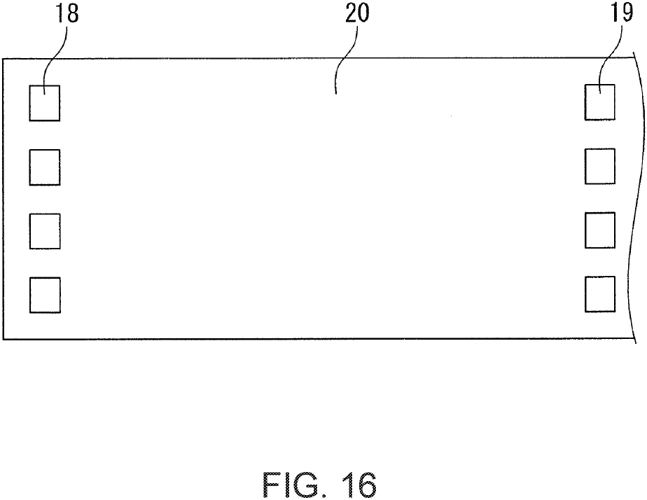

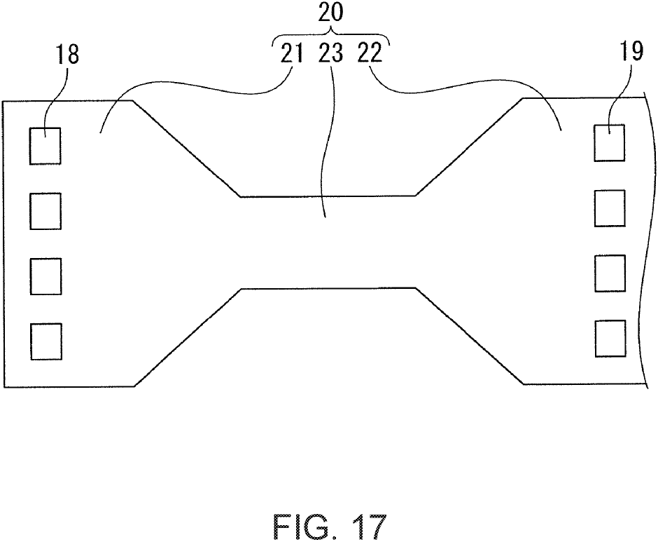

The resistance layer 20 has a rectangular planar shape, as shown in FIG. 16, for example. Alternatively, as shown in FIG. 17, the resistance layer 20 may function as a fuse by forming a shape that melts when an overcurrent flows, for example. In this example, the resistance layer 20 has wide portions 21 and 22 and a narrow portion 23 sandwiched between the wide portions 21 and 22. When an overcurrent flows through the resistance layer 20, the narrow portion 23 melts. By causing the resistance layer 20 to function as a fuse, the resistance layer 20 will be in an open state even if the MIM capacitor is dielectrically broken down, and a short-circuit failure of the power device can be prevented. Other configurations of the semiconductor device 1a of the second embodiment are substantially the same as those of the semiconductor device 1 of the first embodiment, and redundant description will be omitted.

The semiconductor device 1a according to the second embodiment has the same effect as the semiconductor device 1 according to the first embodiment. Furthermore, according to the semiconductor device 1a of the second embodiment, the resistance layer 20 is further provided, and by connecting the resistance R2 of the resistive element formed by the resistance layer 20 to the capacitances C1, C2, and C3, thereby using the resistor R2 as a main resistor element, the resistivity in the resistor R1 of the resistive element formed by the semiconductor substrate 11 can be made very low. When the resistivity of the resistor R1 of the semiconductor substrate 11 is lowered, a substrate having a low resistivity such as a silicon substrate doped with n-type impurities at a high concentration can be used as the semiconductor substrate 11.

### Third Embodiment

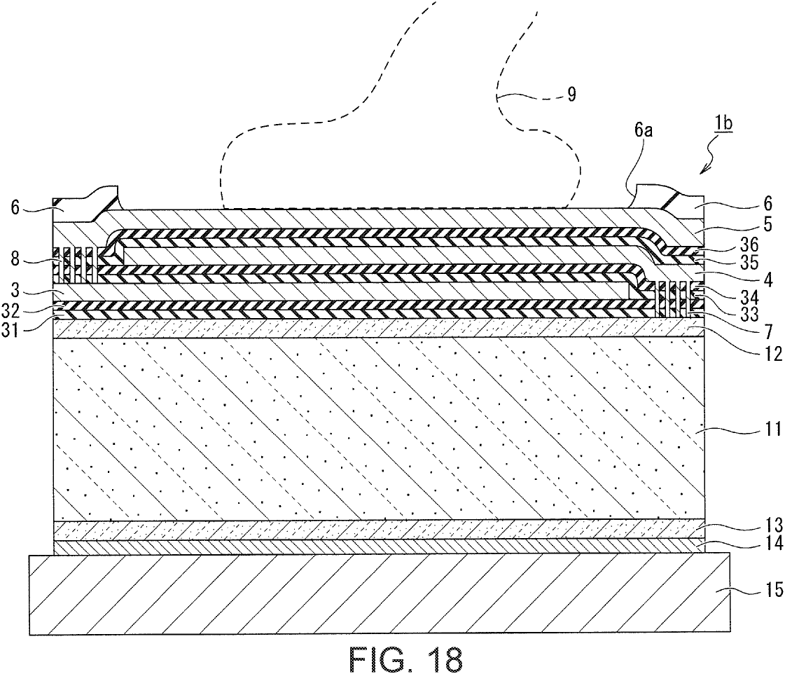

As shown in FIG. 18, the semiconductor device 1b according to a third embodiment differs from the semiconductor device 1 of the first embodiment in that it does not have a lower electrode 2, which is a metal electrode, on a semiconductor substrate 11. In the semiconductor device 1b of the third embodiment, the high-concentration region 12 in the upper portion of the semiconductor substrate 11 constitutes the lower electrode. That is, the high-concentration region 12, the dielectric layers (31, 32), and the first upper electrode 3 constitute the lowest capacitor (3, 12, 31, 32).

The dielectric layers (31, 32) are in contact with the upper surface of the high-concentration region 12 in the upper portion of the semiconductor substrate 11. The vias 7 that penetrate the dielectric layers (31 , 32) are in ohmic contact with the high concentration region 12 on top of the semiconductor substrate 11. The second upper electrode 4 is electrically connected to the high concentration region 12 on the semiconductor substrate 11 through the vias 7 that penetrate the dielectric layers (31, 32). Other configurations of the semiconductor device 1b of the third embodiment are substantially the same as those of the semiconductor device 1 of the first embodiment, and redundant description will be omitted.

According to the semiconductor device 1b of the third embodiment, the same effects as those of the semiconductor device 1 of the first embodiment can be obtained even when the lower electrode 2 is not provided on the semiconductor substrate 11.

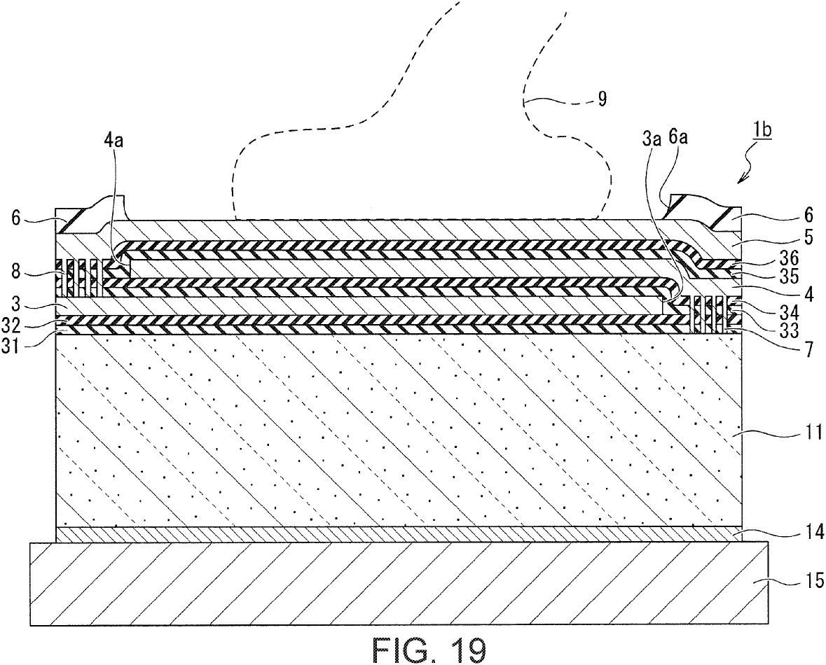

In the semiconductor device 1b of the third embodiment, as shown in FIG. 19, the entire semiconductor substrate 11 may be a high-concentration region with a low resistivity, and the entire semiconductor substrate 11 may constitute a lower electrode. In this case, the semiconductor substrate 11, the dielectric layers (31, 32) and the first upper electrode 3 form the lowest layer capacitor (11, 3, 31, 32). A semiconductor device 1b of the third embodiment functions as a capacitive device chip.

### Fourth Embodiment

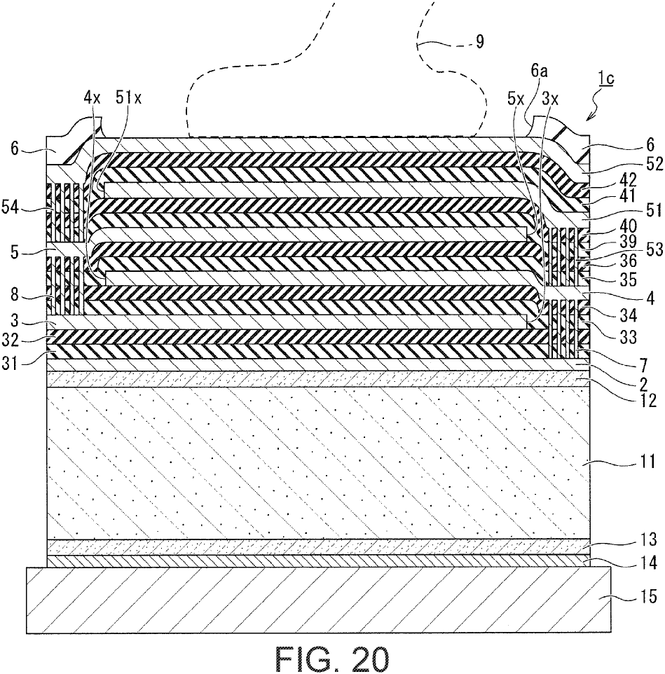

As shown in FIG. 20, a semiconductor device 1c according to a fourth embodiment differs from the semiconductor device 1 of the first embodiment in that it further includes a fourth upper electrode 51 provided over a third upper electrode 5 via dielectric layers (39, 40), and a fifth upper electrode 52 provided over the fourth upper electrode 51 via dielectric layers (41, 42). The fifth upper electrode 52 is the uppermost electrode, and the protective film 6 is provided on the fifth upper electrode 52.

The second upper electrode 4 and the fourth upper electrode 51 are electrically connected through vias 53 penetrating the dielectric layers (35, 36) and the dielectric layers (39, 40). The vias 53 and 7 are arranged in overlapping positions to form a stacked via structure.

The third upper electrode 5 and the fifth upper electrode 52 are electrically connected through vias 54 penetrating the dielectric layers (39, 40) and the dielectric layers (41, 42). The vias 54 and 8 are arranged in overlapping positions to form a stacked via structure. Other configurations of the semiconductor device 1c of the fourth embodiment are substantially the same as those of the semiconductor device 1 of the first embodiment, and redundant description will be omitted.

The semiconductor device 1c according to the fourth embodiment has the same effect as the semiconductor device 1 according to the first embodiment. Furthermore, according to the semiconductor device 1c of the fourth embodiment, a capacitor formed by the third upper electrode 5, the dielectric layer (39, 40), and the fourth upper electrode 51 and a capacitor formed by the fourth upper electrode 51, the dielectric layers (41, 42), and the fifth upper electrode 52 are further connected in parallel with the capacitors C1, C2, and C3 shown in FIG. 4, which are connected in parallel with each other. Here, additional metal electrodes and IMDs may be alternately stacked over this structure so as to connect additional capacitances in parallel.

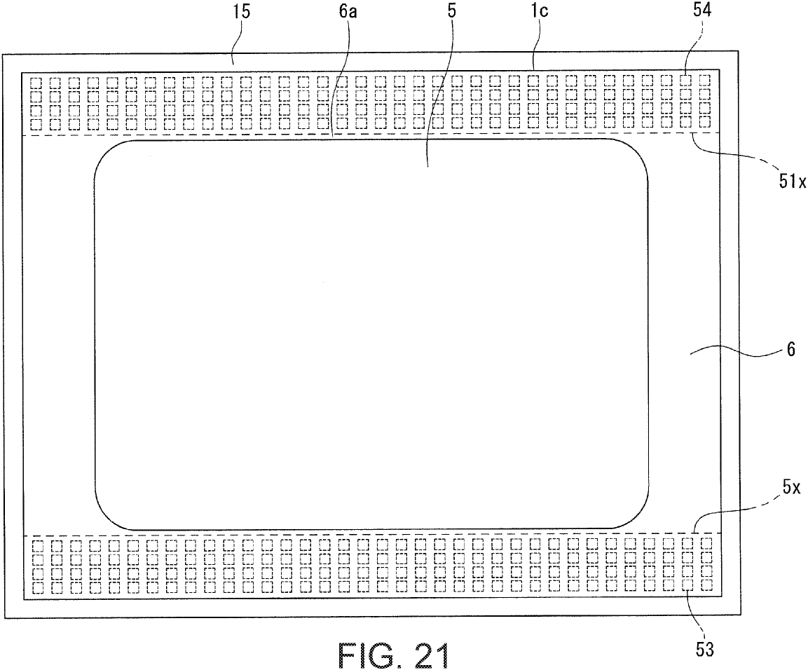

It should be noted that in the semiconductor device 1c of the fourth embodiment, the vias 53 and 54 do not have to be arranged at positions overlapping the vias 7 and 8, respectively. For example, the vias 7 and 8 may be arranged at respective longitudinal ends in FIG. 2, but the vias 53 and 54 may arranged at respective ends in the width direction, as shown in FIG. 21, for example. FIG. 21 schematically shows the positions of the vias 53 and 54, the position of the end 5x of the third upper electrode 5, and the position of the end 51x of the fourth upper electrode 51 with the dashed lines.

The end 5x of the third upper electrode 5 on the side of the via 53 is arranged inward from the end of the semiconductor device 1c of the fourth embodiment so as to be separated from the vias 53. The end 51x of the fourth upper electrode 51 on the side of the vias 54 is arranged inward from the end of the semiconductor device 1c of the fourth embodiment so as to be separated from the vias 54. In the planar pattern, the arrangement positions of the vias 53 and 54 are made different from the arrangement positions of the vias 7 and 8, and the vias 7, 8 and the vias 53, 54 are arranged on different sides of the rectangle of the semiconductor device 1c in this example of the fourth embodiment. Because of this, the flatness of the dielectric layers (39, 40), the fourth upper electrode 51, the dielectric layers (41, 42), and the fifth upper electrode 52 can be maintained.

### Other Embodiments

As described above, the present invention has been described according to the first to fourth embodiments, but it should be understood that the statements and drawings forming part of this disclosure do not unduly limit the present invention. Various alternative embodiments, implementations and operational techniques will become apparent to those skilled in the art from this disclosure.

For example, although the RC snubber circuit 103 of the power conversion circuit is illustrated as the semiconductor device 1 in the first embodiment, the semiconductor device of the present invention can be applied to various circuits other than the power conversion circuit. Further, when the semiconductor substrate 11 of the semiconductor devices 1, 1a, and 1c of the first, third and fourth embodiments is made of a low resistivity substrate, the devices can be used as a capacitor chip for various circuits.

Also, the configurations disclosed in the first to fourth embodiments and their modification examples above can be appropriately combined as long as it does not cause contradiction. Thus, the present invention naturally includes various embodiments and the like that are not described here. Therefore, the technical scope of the present invention is defined only by the matters specifying the invention according to the scope of claims that are valid from the above description. It will be apparent to those skilled in the art that various modifications and variations can be made in the present invention without departing from the spirit or scope of the invention. Thus, it is intended that the present invention cover modifications and variations that come within the scope of the appended claims and their equivalents. In particular, it is explicitly contemplated that any part or whole of any two or more of the embodiments and their modifications described above can be combined and regarded within the scope of the present invention.

What is claimed is:

1. A semiconductor device, comprising:
a lower electrode;
a first dielectric layer provided on the lower electrode;
a first upper electrode provided on the first dielectric layer;
a second dielectric layer provided on the first upper electrode;
a second upper electrode provided on the second dielectric layer and electrically connected to the lower electrode;
a third dielectric layer provided on the second upper electrode; and
a third upper electrode provided on the third dielectric layer and electrically connected to the first upper electrode,
wherein a first capacitor between the lower electrode and the first upper electrode, a second capacitor between the first upper electrode and the second upper electrode, and a third capacitor between the second upper electrode and the third upper electrode are connected in parallel with each other.

2. The semiconductor device according to claim 1, further comprising:
a first via penetrating the first dielectric layer and the second dielectric layer and electrically connecting the lower electrode and the second upper electrode; and
a second via penetrating the second dielectric layer and the third dielectric layer and electrically connecting the first upper electrode and the third upper electrode.

3. The semiconductor device according to claim 2, wherein a lateral end of the first upper electrode is spaced apart from the first via, and a lateral end of the second upper electrode is spaced apart from the second via.

4. The semiconductor device according to claim 2, wherein the first via is arranged at a position overlapping with the third upper electrode in a plan view.

5. The semiconductor device according to claim 1, further comprising a protective film provided on the third upper electrode,
wherein the protective film has an opening to expose a portion of the third upper electrode, the exposed portion of the third upper electrode serving as a pad area capable of wire bonding.

6. The semiconductor device according to claim 1, further comprising a semiconductor substrate provided under the lower electrode.

7. The semiconductor device according to claim 6, wherein said semiconductor substrate is connected in series with said first to third capacitors as a resistive element.

8. The semiconductor device according to claim 6, further comprising a resistance layer provided on the semiconductor substrate via an insulating film,
wherein the resistance layer is electrically connected between the semiconductor substrate and the lower electrode.

9. The semiconductor device according to claim 8, wherein said resistance layer functions as a fuse.

10. The semiconductor device according to claim 1, further comprising a semiconductor substrate,
wherein the lower electrode is made of a high-inpurity semiconductor region provided on an upper part of the semiconductor substrate, and
wherein the semiconductor substrate is connected in series with the first to third capacitors as a resistive element.

11. The semiconductor device according to claim 1, wherein the lower electrode is made of a semiconductor substrate.

12. The semiconductor device according to claim 1, further comprising:
a fourth dielectric layer provided on the third upper electrode;
a fourth upper electrode provided on the fourth dielectric layer and electrically connected to the second upper electrode;
a fifth dielectric layer provided on the fourth upper electrode; and
a fifth upper electrode provided on the fifth dielectric layer and electrically connected to the third upper electrode.

13. The semiconductor device according to claim 11, further comprising:
a first via penetrating the first dielectric layer and the second dielectric layer and electrically connecting the lower electrode and the second upper electrode;
a second via penetrating the second dielectric layer and the third dielectric layer and electrically connecting the first upper electrode and the third upper electrode;
a third via penetrating the third dielectric layer and the fourth dielectric layer and electrically connecting the second upper electrode and the fourth upper electrode; and
a fourth via penetrating through the fourth dielectric layer and the fifth dielectric layer and electrically connecting the third upper electrode and the fifth upper electrode;.

14. The semiconductor device according to claim 13, wherein the first via and the third via are arranged at positions overlapping each other in a plan view, and the second via and the fourth via are arranged at positions overlapping each other in the plan view.

15. The semiconductor device according to claim 13, wherein at least some of the first, second, third and the fourth vias are arranged on different sides of a rectangle formed by the lower electrode in a plan view.

16. The semiconductor device according to claim 1, wherein each of the first, second and third dielectric layers is a multilayered film made of a first dielectric film and a second dielectric film on the first dielectric film.

17. The semiconductor device according to claim 16, wherein the first dielectric film is a TEOS film with a thickness of about 3 µm, and the second dielectric film is a PSG film.
